(19) United States
(12) Patent Application Publication
(10) Pub. No.: US 2007/0188260 A1
(43) Pub. Date: Aug. 16, 2007

(54) RECEIVER INPUT CIRCUIT

(75) Inventor: Kazuo Kawai, Tokyo (JP)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(73) Assignee: GENERAL RESEARCH OF ELECTRONICS, INC., Tokyo (JP)

(21) Appl. No.: 11/674,270

(22) Filed: Feb. 13, 2007

(30) Foreign Application Priority Data
Feb. 14, 2006 (JP) 2006-36966

(51) Int. Cl. H03H 7/38

(52) U.S. Cl. 333/32

(57) ABSTRACT

The present invention provides a receiver input circuit capable of maintaining impedance matching with an antenna feeder wire within all frequency bands to be used and constituting parallel resonant circuits in multi-stage form without using additional circuit portions. The receiver input circuit includes a constant resistance branching filter, a coupling inductor and a tuning circuit. The constant resistance branching filter comprises a low-pass filter and a high-pass filter having termination resistors connected thereto. The low-pass filter and the high-pass filter respectively have equal cut-off frequencies selected to frequencies slightly lower than those lying in a used frequency band and include input ends connected in common to an input terminal of the constant resistance branching filter connected to the antenna feeder wire. The tuning circuit has a parallel resonant circuit constituted of a tuning inductor and a variable capacitance diode. The coupling inductor is connected between a midtap of an inductor of the high-pass filter and an input end of the parallel resonant circuit. An output end of the parallel resonant circuit is connected to a high-frequency circuit.

### RELATED/PRIORITY APPLICATION

This application claims priority with respect to Japanese Application No. 2006-36966, filed Feb. 14, 2006.

### BACKGROUND OF THE INVENTION

1. Field of the Invention

The present invention relates to a receiver input circuit, and particularly to a receiver input circuit which is connected between an antenna feeder wire and a high-frequency circuit and in which an input impedance matching circuit and a tuning circuit are integrally constituted.

2. Description of the Related Art

In general, a receiver input circuit is connected and located between an antenna feeder wire and a high-frequency circuit. Ones having various circuit forms have been used according to the functions of receivers. As one of receiver input circuits used in relatively large numbers, there has been known one in which a midtap is provided in a tuning inductor of a parallel resonant circuit constituting a tuning circuit and a variable capacitance capacitor is connected between the midtap and an antenna feeder wire, and the capacitance value of the variable capacitance capacitor is changed as the tuning frequency of the parallel resonant circuit changes, thereby performing impedance matching between the parallel resonant circuit and the antenna feeder wire. As another one, there has been known one in which as an alternative to the provision of the midtap in the tuning inductor of the parallel resonant circuit constituting the tuning circuit, a transformer structure is used in which a tuning inductor is configured as a primary winding and a secondary winding is coupled to the primary winding, and its secondary winding side is configured as a tuning inductor and its primary winding side is set smaller than the secondary winding side in the number of turns, and in this state, an impedance matching variable capacitance capacitor is connected between the primary winding and an antenna feeder wire and the capacitance value of the variable capacitance capacitor is changed as a tuning frequency of a parallel resonant circuit changes, thereby performing impedance matching between the parallel resonant circuit and the antenna feeder wire. As a further one, there has been known one in which as an alternative to the provision of the midtap in the tuning inductor of the parallel resonant circuit constituting the tuning circuit, a variable capacitance capacitor having a small capacitance value and a variable capacitance capacitor having a large capacitance value are connected in series to the tuning inductor and a connecting point of both variable capacitance capacitors is connected to an antenna feeder wire, and in this state, a tuning frequency is mainly adjusted by the variable capacitance capacitor having the small capacitance value and impedance matching is mainly adjusted by the variable capacitance capacitor having the large capacitance value.

Any of these receiver input circuits needs to perform an adjustment to the resonant frequency of the parallel resonant circuit constituting the tuning circuit and an adjustment to the impedance matching between the parallel resonant circuit and the antenna feeder wire each time it receives a signal from each receiving station targeted for reception. Therefore, in order to obtain the best point for both of the adjustment to the resonant frequency of the parallel resonant circuit constituting the tuning circuit and the adjustment to the impedance matching between the parallel resonant circuit and the antenna feeder wire without performing both adjustments in a state of being independent of each other, it is necessary that both adjustments are repeatedly executed several times alternately to obtain the best point for both adjustments as a result of their repeated execution. Thus, when the receiver receives many receiving stations one after another, there is a need to perform the two adjustments each time it receives radio waves from the respective receiving stations. Therefore, it is necessary to take much time up to the completion of these adjustments and expend many efforts.

There has been a growing trend in recent years to allocate uses of radio waves in specific frequency bands according to usage purposes of the radio waves with an increase in communication demand and expansion of frequency bands of usable radio waves. Therefore, a large number of receiving stations made different in frequency little by little exist in each of narrow frequency bands at the respective frequency bands. It can be said that searching of a desired radio wave from these many receiving stations when a receiver selects a specific receiving station, while the above two of the adjustment to the resonant frequency of the parallel resonant circuit constituting the tuning circuit and the adjustment to the impedance matching between the parallel resonant circuit and the antenna feeder wire are being performed, is an extremely unrealistic means. Therefore, in most recent years, only the adjustment to the resonant frequency of the parallel resonant circuit constituting the tuning circuit is simply made at the receiver input circuit without performing the adjustment of impedance matching in particular, or the selection of a desired radio wave and the setting of a frequency selectivity characteristic of a received signal by simple use of a broadband pass filter have been increasingly referred to a channel selecting function and a frequency selectivity characteristic setting function at an intermediate frequency stage for processing an intermediate frequency signal obtained by frequency-converting the received signal or at a circuit portion subsequent to the intermediate frequency stage.

At the receiver input circuit, however, such a circuit means as to simply perform only the adjustment to the resonant frequency of the parallel resonant circuit constituting the tuning circuit without performing the above adjustment to the impedance matching is of such a type that the adjustment to the impedance matching is fixed to an approximate point. Therefore, it has the drawback that although a desired characteristic is roughly obtained as the frequency selectivity characteristic relative to the selected received signal, a noise factor of the received signal is rather degraded. On the other hand, such a circuit means as to simply use the wideband pass filter alone is of such a type that many received signals different in frequency are simultaneously applied to a frequency converter. Therefore, it has the drawbacks that an image selectivity characteristic and an intermodulation characteristic with respect to the selected received signal are inevitably degraded and the degree of an improvement in noise factor cannot be expected either.

Incidentally, it is understood that it is the best means to provide an input matching circuit that performs the adjustment to the resonant frequency of the parallel resonant circuit constituting the tuning circuit and the adjustment to the impedance matching between the parallel resonant circuit and the antenna feeder wire as in the conventional receiver input circuit for the purpose of enhancing frequency selectivity for each selected received signal and improving a noise factor at the receiver input circuit. Thus, in order to realize the best means referred to above, the present applicant has proposed as Japanese Patent Application No. 2005-292764, a receiver input circuit wherein a circuit means that makes it unnecessary to perform the adjustment to the impedance matching between the parallel resonant circuit and the antennal feeder wire, is disposed therein and the parallel resonant circuit is driven by the output of the circuit means.

The proposed receiver input circuit is of such a type that since it is unnecessary to perform the adjustment to the impedance matching between the parallel resonant circuit and the antenna feeder wire, a four-terminal R-∞ type low-pass filter in which an input termination resistor indicates a resistance value R equal to a characteristic impedance value of the antenna feeder wire and an output termination resistor indicates an infinite resistance value, is connected between the parallel resonant circuit and the antenna feeder wire. The four-terminal R-∞ type low-pass filter takes advantage of the fact that the input side may be terminated with the resistance value R and the output side may be terminated with the infinite resistance value (which may be a resistance value considerably higher than the resistance value R). Even though a resonant impedance value of a parallel tuning circuit changes with a change in selected frequency when the parallel tuning circuit is driven by the output of the four-terminal R-∞ type low-pass filter, a signal transmission characteristic is maintained so long as the resonant impedance value is held at an impedance value considerably higher than the resistance value R.

The four-terminal R-∞ type low-pass filter used in the proposed receiver input circuit is derived or produced using only the condition that when the termination resistor having the resistance value R is connected to the input side and the termination resistor having the infinite resistance value is connected to the output side, a signal transmission characteristic identical to that for a pre-conversion low-pass filter in which the termination resistor having the resistance value R is connected to both of the input and output sides thereof, can be obtained. Thus, compensation for the characteristic other than the signal transmission characteristic, e.g., an input/output impedance characteristic is not made. Therefore, the impedance matching between the parallel resonant circuit and the antenna feeder wire needs to pay attention to reflection from the antenna feeder wire except that the impedance matching may not be so emphasized as in the cases where the length of the antenna feeder wire is so short and a booster amplifier is connected within the antenna feeder wire.

When the frequency selectivity of the parallel resonant circuit constituting the tuning circuit must be made sharp at the proposed receiver input circuit, there is a need to construct the parallel resonant circuits each constituting the tuning circuit in a two-stage configuration or a multi-stage configuration with stages greater than the two stages. If a center frequency is fixed as in an intermediate frequency amplifier in this case, intermediate frequency amplifiers multi-staged in stagger form are adopted with relative ease. However, the stagger type multi-staged circuit needs to maintain, in designated states, the resonant frequencies and Q of the respective parallel resonant circuits configured in multi-stage form, and the degree of coupling between the parallel resonant circuit and each of the parallel resonant circuits disposed before and after it. Since, however, the resonant impedance values of the parallel resonant circuits of the respective stages also change where the center frequency of the received signal changes by channel selection as in the receiver input circuit, the degree of coupling between the parallel resonant circuit and each of the parallel resonant circuits placed before and after it also changes, thereby encountering difficulties in maintaining one of basic conditions as for the stagger type multi-staged circuit.

In this case, buffer amplifiers may respectively be inserted between the pre-stage parallel resonant circuits and the next-stage parallel resonant circuits to configure the stagger type multi-staged circuit that avoids such difficulty. If, however, the buffer amplifiers are connected to coupling portions of the respective parallel resonant circuits, then the receiver input circuit increases in circuit scale and correspondingly, its manufacturing cost rises.

### SUMMARY OF THE INVENTION

The present invention has been made in view of such a technical background. It is therefore an object of the present invention to provide a receiver input circuit capable of maintaining impedance matching with an antenna feeder wire throughout a used frequency band and configuring parallel resonant circuits in multi-stage form without using additional circuit portions when it is desired to make frequency selectivity sharp.

In order to attain the above object, there is provided a receiver input circuit according to one aspect of the present invention, connected between an antenna feeder wire and a high-frequency circuit, which is equipped with constituting means comprising:

a constant resistance branching filter;

a tuning circuit; and

a coupling inductor that couples the constant resistance branching filter and the tuning circuit to each other,

wherein the constant resistance branching filter comprises a low-pass filter and a high-pass filter both having termination resistors connected thereto,

wherein the low-pass filter and the high-pass filter respectively have cut-off frequencies equal to each other, which are selected to frequencies slightly lower than those in a used frequency band, and have input ends respectively connected so as to share an input terminal of the constant resistance branching filter, which is connected to the antenna feeder wire,

wherein the tuning circuit has a parallel resonant circuit comprising a tuning inductor and a variable capacitance diode,

wherein the coupling inductor is connected between a midtap of an inductor constituting the high-pass filter and an input end of the parallel resonant circuit, and

wherein an output end of the parallel resonant circuit is connected to its corresponding receiver input end.

In the constituting means, the tuning circuit is used which comprises a single parallel resonant circuit or comprises a first-stage parallel resonant circuit and a second-stage parallel resonant circuit connected in tandem and wherein a ground end of variable capacitance diode of the first-stage parallel resonant circuit and a ground end of a variable capacitance diode of the second-stage parallel resonant circuit are connected in common, and a commonly-connected point of both ground ends is connected to ground through a high-capacity capacitor having impedance nearly zero to a used frequency. Alternatively, the tuning circuit is used which comprises first-stage, second-stage and third-stage parallel resonant circuits connected in tandem and wherein a ground end of a variable capacitance diode of the first-stage parallel resonant circuit and a ground end of a variable capacitance diode of the second-stage parallel resonant circuit are connected in common, a commonly-connected point of the ground ends of both variable capacitance diodes is connected to ground through a first high-capacity capacitor having impedance nearly zero to a used frequency, a ground end of a tuning inductor of the second-stage parallel resonant circuit and a ground end of a variable capacitance diode of the third-stage parallel resonant circuit are connected in common, and a commonly-connected point of the ground ends of both the tuning inductor and the variable capacitance diode is connected to ground through a second-capacity capacitor having impedance nearly zero to a used frequency.

The process of obtaining the receiver input circuit equipped with the constituting means will now be explained as follows.

In general, a characteristic impedance of an antenna feeder wire is maintained at a value approximately constant with respect to a change in received signal frequency. However, a resonant impedance value of a parallel resonant circuit constituting a tuning circuit changes in proportion to approximately the square with respect to the change in the received signal frequency. Thus, in the present invention, a constant input resistance branching filter is used in an impedance matching circuit that connects a parallel resonant circuit and an antenna feeder wire.

The constant input resistance branching filter is a circuit wherein input terminals of a low-pass filter and a high-pass filter both equal to each other in cut-off frequency (also called “crossover frequency”) are connected in common, and the low-pass and high-pass filters are simultaneously driven by a received signal. Since these low-pass and high-pass filters are respectively terminated by termination resistors, the respective input impedances of the low-pass and high-pass filters complement each other when the received signal frequency changes. Further, the input impedances thereof are kept constant throughout a used frequency band. In this case, the output of the constant input resistance branching filter can be taken out from either of the low-pass filter and the high-pass filter. In the present invention, however, the output of the high-pass filter is used for reasons to be descried below.

That is, since the high-pass filter makes use of its passing band, there is a need to set the crossover frequency of the high-pass filter to a frequency lower than that lying in the used frequency band. If the crossover frequency of the high-pass filter is set to a frequency as close to the lower end of the used frequency band as possible, then attenuation based on an attenuation characteristic of the high-pass filter and attenuation based on an attenuation characteristic of the parallel resonant circuit constituting the tuning circuit can be added together, thus making it possible to improve selectivity of a low-pass frequency.

In general, a capacitor having a small capacitance value is normally used as a drive coupling element used when the parallel resonant circuit constituting the tuning circuit is driven. In the present invention, however, an inductor is used for reasons to be described below.

That is, the resonant impedance value of the parallel resonant circuit constituting the tuning circuit changes in proportion to approximately the square of a receive frequency. When, at this time, a capacitor is used as the drive coupling element for driving the parallel resonant circuit, its impedance changes in inverse proportion to the receive frequency. Therefore, the directions in which the resonant impedance value of the parallel resonant circuit and the impedance value of the capacitor change with respect to the change in the receive frequency become opposite to each other. When the inductor is used as the drive coupling element in contrast, its impedance changes in proportion to the receive frequency and hence its change becomes identical in direction to the change in the resonant impedance of the parallel resonant circuit. Therefore, a change in signal gain at the time that the receive frequency changes, is reduced when the inductor is used as the drive coupling element as compared with the use of the capacitor as the drive coupling element. Thus, the inductor is used as the drive coupling element in the present invention.

When the parallel resonant circuit constituting the tuning circuit is drive by the output of the high-pass filter, the resonant impedance value of the parallel resonant circuit normally becomes considerably higher than the termination resistance value of the high-pass filter. Therefore, when the output of the high-pass filter and the parallel resonant circuit are coupled to each other by the drive coupling element, it is necessary to couple them through an inductor having an impedance value that is as high as possible. If, at this time, the output at the point placed in a low impedance state, i.e., the midtap of the inductor constituting the high-pass filter is used without using the original output of the high-pass filter where the output of the high-pass filter and the parallel resonant circuit are coupled to each other, then the output of the high-pass filter is little affected even though the total impedance value of the coupling inductor and the parallel resonant circuit substantially changes with a change in the resonant frequency of the parallel resonant circuit.

When the inductor is used as the drive coupling element, the total frequency characteristics of the inductor and the parallel resonant circuit constituting the tuning circuit serve such that the coupling inductor assumes a low-pass characteristic. Therefore, the amount of attenuation on the side of the lower-pass frequency than the resonant frequency becomes lower than the amount of attenuation on the high-pass side. Using the output of the high-pass filter in the constant resistance branching filter makes it possible to cause the amount of attenuation with respect to upper and lower frequencies of the resonant frequency of the parallel resonant circuit to approach a state of equilibrium.

Further, parallel resonant circuits are generally used for the tuning circuit. When the parallel resonant circuits constituting the tuning circuit are connected in multi-stage form, a voltage signal of the pre-stage parallel resonant circuit is transmitted to the next-stage parallel resonant circuit. When, however, the resonant frequency for parallel resonance is changed, a resonant impedance changes with the resonant frequency and correspondingly, a signal gain also changes. Therefore, in such a system as to transmit the voltage output, the amount of mutual interference between the pre-stage parallel resonant circuit and the next-stage parallel resonant circuit changes. In order to avoid such a situation, a current output may be transmitted. That is, if each parallel resonant circuit constituting the tuning circuit is operated as a series resonant circuit, then a reactance component is cancelled at a resonant point even though the resonant frequency changes, so that only a resistance component remains. It is therefore possible to transmit a current output proportional to the resistance value of the resistance component. Even when the parallel resonant circuits are connected in three-stage form as well as the two-stage connection of the parallel resonant circuits, a current output can be transmitted in like manner. Incidentally, the output of the final-stage parallel resonant circuit may be taken out of one end (terminal on the hot side) of the normal parallel resonant circuit in the same manner as the output of the normal parallel resonant circuit.

According to the receiver input circuit according to the present invention as descried above in detail, it includes a constant resistance branching filter, a tuning circuit and a coupling inductor that couples the constant resistance branching filter and the tuning circuit to each other. The constant resistance branching filter comprises a low-pass filter and a high-pass filter to which termination resistors are respectively connected. The low-pass filter and the high-pass filter respectively have equal cut-off frequencies selected to frequencies slightly lower than those lying in a used frequency band and are connected in such a manner that their input ends share an input terminal of the constant resistance branching filter, which is connected to an antenna feeder wire. Therefore, an advantageous effect is brought about in that a receiver input circuit is obtained in which even when a resonant frequency of a parallel resonant circuit constituting the tuning circuit is changed, impedance matching between the parallel resonance circuit and the antenna feeder wire can be attained without its adjustment regardless of the use of a constant resistance branching filter having a relatively simple circuit configuration, and multistaging of the parallel resonant circuits for enhancing the frequency selectivity characteristic of the tuning circuit can easily be realized and both frequency selectivity and a noise factor are respectively improved.

Other features and advantages of the present invention will become apparent upon a reading of the attached specification.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein like reference numerals identify like elements in which:

FIG. 1 shows a first embodiment of a receiver input circuit according to the present invention and is a circuit diagram illustrating a circuit configuration thereof;

FIG. 2 is a characteristic diagram showing one example of frequency selectivity obtained in the receiver input circuit illustrated in FIG. 1;

FIG. 3 depicts a second embodiment of a receiver input circuit according to the present invention and is a circuit diagram showing a circuit configuration thereof;

FIG. 4 is a characteristic diagram showing one example of frequency selectivity obtained in the receiver input circuit illustrated in FIG. 3;

FIG. 5 shows a third embodiment of a receiver input circuit according to the present invention and is a circuit diagram showing a circuit configuration thereof; and

FIG. 6 is a characteristic diagram showing one example of frequency selectivity obtained in the receiver input circuit illustrated in FIG. 5.

### DETAILED DESCRIPTION OF THE PREFERRED EMBODIMENTS

Preferred embodiments of the present invention will be explained hereinafter with reference to the accompanying drawings.

### First Preferred Embodiment

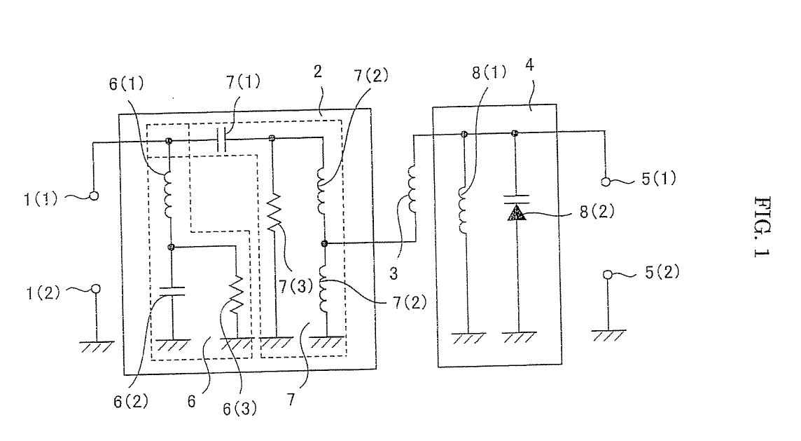

FIG. 1 shows a first embodiment of a receiver input circuit according to the present invention and is a circuit diagram showing a circuit configuration thereof. As shown in FIG. 1, the receiver input circuit according to the first embodiment comprises a pair of input terminals 1(1) and 1(2), a constant resistance branching filter 2, a coupling inductor 3, a parallel resonant circuit 4 constituting a single-stage tuning circuit and a pair of output terminals 5(1) and 5(2). The constant resistance branching filter 2 includes a low-pass filter 6 constituted of a series inductor 6(1), a branching capacitor 6(2) and a termination resistor 6(3), and a high-pass filter 7 constituted of a series capacitor 7(1), a branching inductor 7(2) with a midtap and a termination resistor 7(3). The parallel resonant circuit 4 comprises a parallel-connected circuit constituted of a tuning inductor 8(1) and a tuning varactor diode 8(2).

In this case, in the constant resistance branching filter 2, an input end of the low-pass filter 6 and an input end of the high-pass filter 7 are connected in common to the input terminal 1(1). The midtap of the branching inductor 7(2) constituting the high-pass filter 7 is connected to one end (terminal on the hot side) of the parallel resonant circuit 4 through the coupling inductor 3. One end (terminal on the hot side) of the parallel resonant circuit 4 is connected to the output terminal 5(1). In addition to the above, the pair of input terminals 1(1) and 1(2) is connected to an unillustrated antenna feeder wire, and the pair of output terminals 5(1) and 5(2) is connected to a high-frequency circuit unillustrated in like manner.

The low-pass and high-pass filters 6 and 7 that constitute the constant resistance branching filter 2 are respectively configured so as to have the same cut-off frequencies selected to frequencies slightly lower than those lying in a frequency band to be used. Thus, when each of received signals lying in the used frequency band is inputted, the received signal is cut off by the low-pass filter 6 because the low-pass filter 6 is within a cut-off region of the received signal, whereas since the high-pass filter 7 is placed in a passage region of the received signal, the received signal passes through the high-pass filter 7 and is then supplied to the branching inductor 7(2).

The receiver input circuit having the above configuration is operated as follows:

When received signals are supplied to the input terminals 1(1) and 1(2) through the antenna feeder wire and applied to the constant resistance branching filter 2 through the input terminals 1(1) and 1(2), the received signals pass through the high-pass filter 7 in the constant resistance branching filter 2 and are supplied to the branching inductor 7(2). Thereafter, the received signals are led out from the midtap of the branching inductor 7(2) which assumes impedance low with respect to a ground point, after which they are supplied to the parallel resonant circuit 4 through the coupling inductor 3 having a large inductance value, thereby driving the parallel resonant circuit 4. At this time, the tuning varactor diode 8(2) in the parallel resonant circuit 4 is supplied with a channel selection voltage from an unillustrated variable dc bias circuit so that its capacitance value is controlled. Thus, the parallel resonant circuit 4 is parallel-resonated at a resonant frequency determined according to the inductance value of the tuning inductor 8(1) and the capacitance value of the tuning varactor diode 8(2). Therefore, only the received signal corresponding to the parallel resonant frequency, of the driven-supplied received signals is selected and supplied from the parallel resonant circuit 4 to the unillustrated high-frequency circuit through the output terminals 5(1) and 5(2).

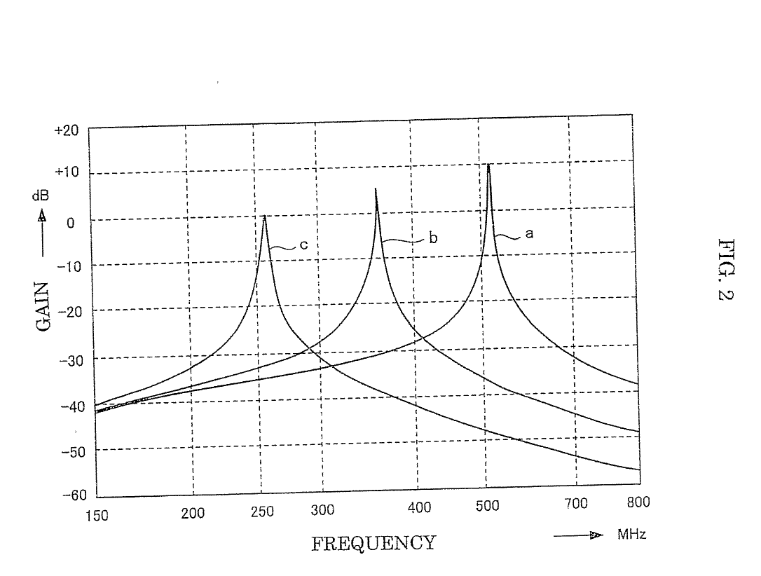

Here, FIG. 2 is a characteristic diagram showing one example of frequency selectivity at the receiver input circuit shown in FIG. 1.

In FIG. 2, the horizontal axis indicates a received signal frequency expressed in MHz, and the vertical axis indicates received signal gain expressed in dB.

The frequency selectivity characteristics illustrated in FIG. 2 respectively indicate frequency selectivity characteristics obtained at the time that when the inductance of the series inductor 6(1), the capacitance of the branching capacitor 6(2) and the resistance value of the termination resistor 6(3) are respectively assumed to be 56 nH, 11 pF and 50Ω at the low-pass filter 6, and the capacitance of the series capacitor 7(1), the inductance of the branching inductor 7(2) with the midtap and the resistance value of the termination resistor 7(3) are respectively assumed to be 11 pF, 42 nH and 15 nH, and 50Ω at the high-pass filter 7, the cut-off frequencies of the low-pass filter 6 and the high-frequency filter 7 constituting the constant resistance branching filter 2 are both set to 200 MHz; the characteristic impedance of the antenna feeder wire, the inductance of the coupling inductor 3 and the inductance of the tuning inductor 8(1) are respectively set to 50Ω, 1 μH and 20 nH; and the capacitance of the tuning varactor diode 8(2) is changed to three stages of 5 pF (curve a), 10 pF (curve b) and 20 pF (curve c).

As indicated by the curves a, b and c illustrated in FIG. 2, they represent that although the frequencies at which the maximum gain is obtained, change depending upon changes in the capacitance of the tuning varactor diode 8(2), the degrees of rise steepness of the respective curves a, b and c indicative of the frequency selectivity characteristics take forms approximately identical to one another and no large change occurs in the frequency selectivity. As to the maximum gain at each of the curves a, b and c, a change in gain equivalent to 10 dB or so at a maximum takes place when the resonant frequency of the parallel resonant circuit 4 is changed. This is however due to the fact that Q of the parallel resonant circuit 4 changes with the change in resonant frequency. Thus, the gain change to this extent can easily be corrected by AGC lying in a receiver.

It has been confirmed that the input impedances of the receiver input circuit at the time that the curves a, b and c illustrated in FIG. 2 are obtained, fall within a range of 50Ω±1.5Ω or so in the vicinity of their tuning points. The value of 50Ω±1.5Ω is equivalent to about 0.015 when expressed as a reflection coefficient and corresponds to about 1.03 when expressed in SWR. It can thus be said that the state of impedance matching is extremely good.

### Second Preferred Embodiment

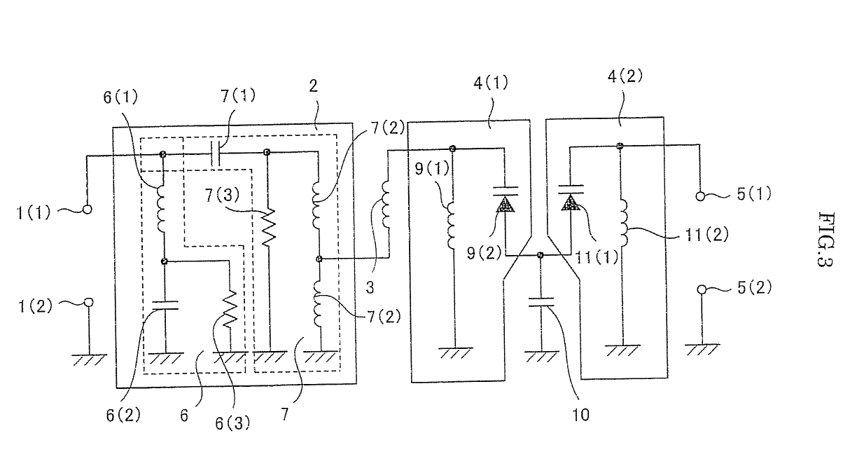

Next, FIG. 3 shows a second embodiment of a receiver input circuit according to the present invention and is a circuit diagram showing its circuit configuration.

In FIG. 3, constituent elements identical to those shown in FIG. 1 are respectively given the same reference numerals.

As shown in FIG. 3, the receiver input circuit according to the second embodiment comprises a pair of input terminals 1(1) and 1(2), a constant resistance branching filter 2, a coupling inductor 3, a first parallel resonant circuit 4(1) and a second parallel resonant circuit 4(2) that constitute a two-stage tuning circuit, a pair of output terminals 5(1) and 5(2) and a coupling capacitor 10. The first parallel resonant circuit 4(1) is constituted of a parallel-connected circuit of a first tuning inductor 9(1) and a first tuning varactor diode 9(2). The second parallel resonant circuit 4(2) is constituted of a parallel-connected circuit of a second tuning varactor diode 11(1) and a second tuning inductor 11(2). The constant resistance branching filter 2 is identical in configuration to the constant resistance branching filter 2 shown in FIG. 1.

In this case, in the first parallel resonant circuit 4(1) and the second parallel resonant circuit 4(2), a high-capacity coupling capacitor 10 is connected between a ground-side terminal for the first tuning varactor diode 9(2) and the second tuning varactor diode 11(1) and ground thereby to couple the first parallel resonant circuit 4(1) and the second parallel resonant circuit 4(2) to each other. One end (terminal on the hot side) of the first parallel resonant circuit 4(1) is connected to a midtap of a branching inductor 7(2) constituting a high-pass filter 7 via the coupling inductor 3, and one end (terminal on the hot side) of the second parallel resonant circuit 4(2) is connected to the output terminal 5(1). Other circuit portions employed in the present embodiment are identical to their corresponding circuit portions illustrated in FIG. 1 in configuration and connection state.

The operation of the receiver input circuit according to the second embodiment based on the above configuration is basically identical to that of the receiver input circuit according to the first embodiment. When received signal are supplied to the input terminals 1(1) and 1(2) through an antenna feeder wire and applied to the constant resistance branching filter 2 through the input terminals 1(1) and 1(2), the received signals pass through the high-pass filter 7 in the constant resistance branching filter 2 and are supplied to the branching inductor 7(2). Thereafter, the received signals are led out from the midtap of the branching inductor 7(2) which assumes impedance low with respect to a ground point, after which they are supplied to the first parallel resonant circuit 4(1) through the coupling inductor 3 having a large inductance value and then supplied even to the second parallel resonant circuit 4(2), thereby driving the first parallel resonant circuit 4(1) and the second parallel resonant circuit 4(2).

At this time, the first tuning varactor diode 9(2) and the second tuning varactor diode 11(1) in the first and second parallel resonant circuits 4(1) and 4(2) are respectively supplied with channel selection voltages from unillustrated variable dc bias circuits so that their capacitance values are controlled. Thus, the first parallel resonant circuit 4(1) is parallel-resonated at a resonant frequency determined according to the inductance value of the first tuning inductor 9(1) and the capacitance value of the first tuning varactor diode 9(2), and the second parallel resonant circuit 4(2) is parallel-resonated at a resonant frequency determined according to the capacitance value of the second tuning varactor diode 11(1) and the inductance value of the second tuning inductor 11(2). Therefore, only the received signals corresponding to the parallel resonant frequencies, of the driven-supplied received signals are respectively selected and supplied from the second parallel resonant circuit 4(2) to their corresponding receiver input terminals via the output terminals 5(1) and 5(2).

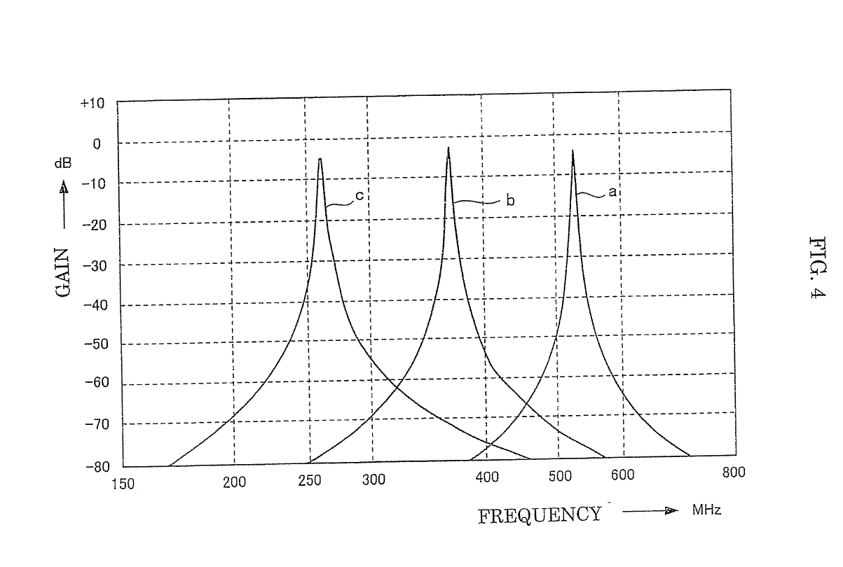

Next, FIG. 4 is a characteristic diagram showing one example of frequency selectivity at the receiver input circuit shown in FIG. 3.

In FIG. 4, the horizontal axis indicates a received signal frequency expressed in MHz, and the vertical axis indicates received signal gain expressed in dB.

The frequency selectivity characteristics illustrated in FIG. 4 respectively indicate frequency selectivity characteristics obtained at the time that the inductance of the first tuning inductor 9(1), the inductance of the second tuning inductor 11(2) and the capacitance value of the coupling capacitor 10 are respectively assumed to be 20 nH, 19 nH and 0.002 μF, and the capacitance of the first tuning varactor diode 9(2) and the capacitance of the second tuning varactor diode 11(1) are respectively changed to three stages of 5 pF (curve a), 10 pF (curve b) and 20 pF (curve c). Incidentally, the resistance and impedance values of the respective constituent elements other than the above are identical to the resistance and impedance values of their corresponding constituent elements used in the characteristic diagram illustrated in FIG. 2.

As indicated by the curves a, b and c illustrated in FIG. 4, they represent that although the frequencies at which the maximum gain is obtained, change depending upon changes in the capacitances of the first and second tuning varactor diode 9(2) and 11(1), the degrees of rise steepness of the respective curves a, b and c indicative of the frequency selectivity characteristics take forms approximately identical to one another and no change occurs in the frequency selectivity. Further, the maximum gain at each of the curves a, b and c remains almost unchanged even when the resonant frequencies of the first and second parallel resonant circuits 4(1) and 4(2) are changed. Incidentally, although the frequency selectivity characteristics indicated by the curves a, b and c are respectively slightly wider in passing bandwidth than those at their corresponding curves a, b and c shown in FIG. 2, this is because mutual interference occurs between the first parallel resonant circuit 4(1) and the second parallel resonant circuit 4(2). The degree of such mutual interference therebetween is determined according to the capacitance of the coupling capacitor 10. The larger the capacitance of the coupling capacitor 10, the lower the mutual interference. Since, however, the signal gain is also reduced simultaneously with it, the capacitance of the coupling capacitor may be determined in consideration of the passing bandwidth and the signal gain.

It has been confirmed that the input impedances of the receiver input circuit at which the curves a, b and c illustrated in FIG. 4 are obtained, fall within a range of 50Ω±1.5Ω or so in the vicinity of their tuning points.

### Third Preferred Embodiment

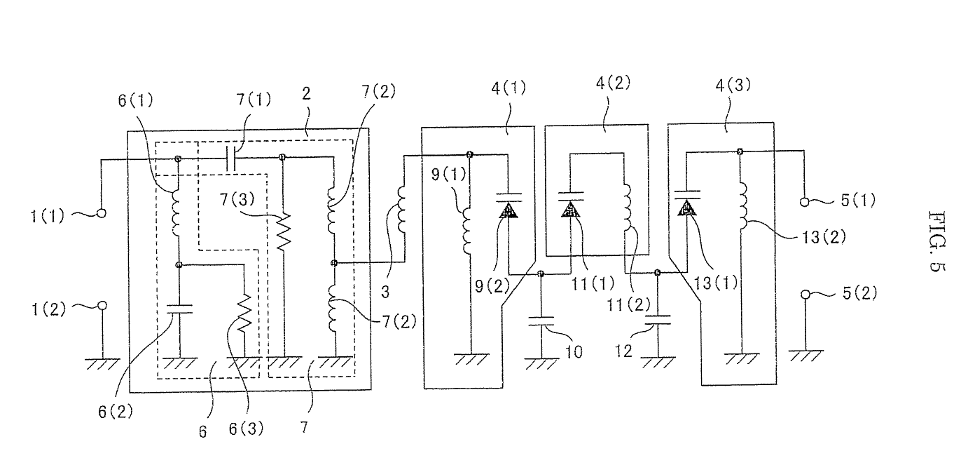

Subsequently, FIG. 5 shows a third embodiment of a receiver input circuit according to the present invention and is a circuit diagram showing a circuit configuration thereof.

In FIG. 5, constituent elements identical to those shown in FIG. 2 are respectively given the same reference numerals.

As shown in FIG. 5, the receiver input circuit according to the third embodiment comprises a pair of input terminals 1(1) and 1(2), a constant resistance branching filter 2, a coupling inductor 3, a first parallel resonant circuit 4(1), a second parallel resonant circuit 4(2) and a third parallel resonant circuit 4(3) that constitute a three-stage tuning circuit, a pair of output terminals 5(1) and 5(2) and two coupling capacitors 10 and 12. The first parallel resonant circuit 4(1) is constituted of a parallel-connected circuit of a first tuning inductor 9(1) and a first tuning varactor diode 9(2). The second parallel resonant circuit 4(2) is constituted of a parallel-connected circuit of a second tuning varactor diode 11(1) and a second tuning inductor 11(2). The third parallel resonant circuit 4(3) is constituted of a parallel-connected circuit of a third tuning varactor diode 13(1) and a third tuning inductor 13(2). Even in the present example, the constant resistance branching filter 2 is identical in configuration to the constant resistance branching filter 2 shown in FIG. 1 or 3.

In this case, in the first parallel resonant circuit 4(1) and the second parallel resonant circuit 4(2), a high-capacity coupling capacitor 10 is connected between a ground-side terminal for the first tuning varactor diode 9(2) and the second tuning varactor diode 11(1) and ground thereby to couple the first parallel resonant circuit 4(1) and the second parallel resonant circuit 4(2) to each other. In the second parallel resonant circuit 4(2) and the third parallel resonant circuit 4(3), a high-capacity coupling capacitor 12 is connected between a ground-side terminal for the second tuning inductor 11(2) and the third tuning varactor diode 13(1) and ground thereby to couple the second parallel resonant circuit 4(2) and the third parallel resonant circuit 4(3) to each other. Even in the present embodiment, one end (terminal on the hot side) of the first parallel resonant circuit 4(1) is connected to a midtap of a branching inductor 7(2) constituting a high-pass filter 7 via the coupling inductor 3, and one end (terminal on the hot side) of the third parallel resonant circuit 4(3) is connected to the output terminal 5(1). Other circuit portions employed in the present embodiment are identical to their corresponding circuit portions illustrated in FIGS. 1 and 3 in configuration and connection state.

The operation of the receiver input circuit according to the third embodiment based on the above configuration is basically identical to that of the receiver input circuit according to the first or second embodiment. The process of the operation up to the supply of received signals to the first parallel resonant circuit 4(1) is identical to the process of the operation of the receiver input circuit according to the first or second embodiment. The operation of the receiver input circuit at the time that the first parallel resonant circuit 4(1), the second parallel resonant circuit 4(2) and the third parallel resonant circuit 4(3) are driven by the received signals will be explained here.

That is, the first tuning varactor diode 9(2), the second tuning varactor diode 11(1) and the third tuning varactor diode 13(1) in the first through third parallel resonant circuits 4(1) through 4(3) are respectively supplied with channel selection voltages from unillustrated variable dc bias circuits so that their capacitance values are controlled. Thus, the first parallel resonant circuit 4(1) is parallel-resonated at a resonant frequency determined according to the inductance value of the first tuning inductor 9(1) and the capacitance value of the first tuning varactor diode 9(2). The second parallel resonant circuit 4(2) is parallel-resonated at a resonant frequency determined according to the capacitance value of the second tuning varactor diode 11(1) and the inductance value of the second tuning inductor 11(2). The third parallel resonant circuit 4(3) is parallel-resonated at a resonant frequency determined according to the capacitance value of the third tuning varactor diode 13(1) and the inductance value of the third tuning inductor 13(2). Therefore, only the received signals corresponding to the parallel resonant frequencies, of the driven-supplied received signals are respectively selected and supplied from the third parallel resonant circuit 4(3) to a high-frequency circuit via the output terminals 5(1) and 5(2).

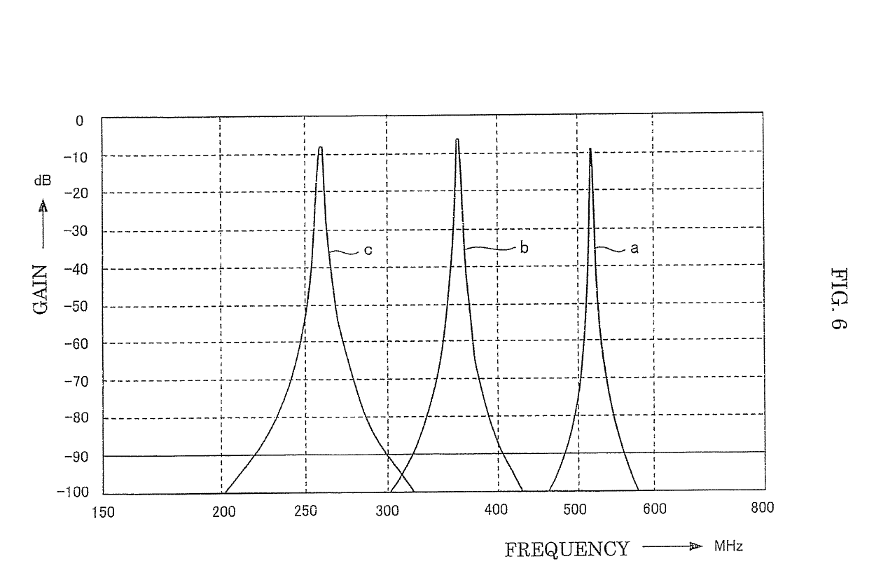

Subsequently, FIG. 6 is a characteristic diagram showing one example of frequency selectivity at the receiver input circuit shown in FIG. 5.

In FIG. 6, the horizontal axis indicates a received signal frequency expressed in MHz, and the vertical axis indicates received signal gain expressed in dB.

The frequency selectivity characteristics illustrated in FIG. 6 respectively indicate frequency selectivity characteristics obtained at the time that the inductance of the first tuning inductor 9(1), the inductances of the second and third tuning inductors 11(2) and 13(2), and the capacitance values of the two coupling capacitors 10 and 12 are respectively assumed to be 20 nH, 19 nH and 0.002 μF, and the capacitance of the first tuning varactor diode 9(2), the capacitance of the second tuning varactor diode 11(1) and the capacitance of the third tuning varactor diode 13(1) are respectively changed to three stages of 5 pF (curve a), 10 pF (curve b) and 20 pF (curve c). Incidentally, the resistance and impedance values of the respective constituent elements other than the above are identical to the resistance and impedance values of their corresponding constituent elements used in the characteristic diagram illustrated in FIG. 2 or 4.

As indicated by the curves a, b and c illustrated in FIG. 6, they represent that although the frequencies at which the maximum gain is obtained, change depending upon changes in the capacitances of the first, second and third tuning varactor diodes 9(2), 11(1) and 13(1), the degrees of rise steepness of the respective curves a, b and c indicative of the frequency selectivity characteristics take forms approximately identical to one another and no change occurs in the frequency selectivity. Further, all of the curves become steeper than their corresponding curves illustrated in FIG. 4. Besides, the maximum gain at each of the curves a, b and c remains almost unchanged even when the resonant frequencies of the first through third parallel resonant circuits 4(1) through 4(3) are changed.

It has been confirmed that the input impedances of the receiver input circuit at which the curves a, b and c illustrated in FIG. 6 are obtained, fall within a range of 50Ω±1.5Ω or so in the vicinity of their tuning points.

While the preferred forms of the present invention have been described, it is to be understood that modifications will be apparent to those skilled in the art without departing from the spirit of the invention. The scope of the invention is to be determined solely by the following claims.

What is claimed is:

1. A receiver input circuit connected between an antenna feeder wire and a high-frequency circuit, comprising:
a constant resistance branching filter;
a tuning circuit; and
a coupling inductor that couples the constant resistance branching filter and the tuning circuit to each other,
wherein the constant resistance branching filter comprises a low-pass filter and a high-pass filter both having termination resistors connected thereto,
wherein the low-pass filter and the high-pass filter respectively have cut-off frequencies equal to each other, which are selected to frequencies slightly lower than those in a used frequency band, and have input ends respectively connected so as to share an input terminal of the constant resistance branching filter, which is connected to the antenna feeder wire,
wherein the tuning circuit has a parallel resonant circuit comprising a tuning inductor and a variable capacitance diode,
wherein the coupling inductor is connected between a midtap of an inductor constituting the high-pass filter and an input end of the parallel resonant circuit, and
wherein an output end of the parallel resonant circuit is connected to the high-frequency circuit.

2. The receiver input circuit according to claim 1, wherein the tuning circuit is constituted of a single parallel resonant circuit.

3. The receiver input circuit according to claim 1, wherein the tuning circuit comprises a first-stage parallel resonant circuit and a second-stage parallel resonant circuit connected in tandem,
wherein a ground end of variable capacitance diode of the first-stage parallel resonant circuit and a ground end of a variable capacitance diode of the second-stage parallel resonant circuit are connected in common, and
wherein a commonly-connected point of both ground ends is connected to ground through a high-capacity capacitor having impedance nearly zero to a used frequency.

4. The receiver input circuit according to claim 1, wherein the tuning circuit comprises first-stage, second-stage and third-stage parallel resonant circuits connected in tandem,
wherein a ground end of a variable capacitance diode of the first-stage parallel resonant circuit and a ground end of a variable capacitance diode of the second-stage parallel resonant circuit are connected in common,
wherein a commonly-connected point of the ground ends of both variable capacitance diodes is connected to ground through a first high-capacity capacitor having impedance nearly zero to a used frequency,
wherein a ground end of a tuning inductor of the second-stage parallel resonant circuit and a ground end of a variable capacitance diode of the third-stage parallel resonant circuit are connected in common, and
wherein a commonly-connected point of the ground ends of both the tuning inductor and the variable capacitance diode is connected to ground through a second-capacity capacitor having impedance nearly zero to a used frequency.
